(19) United States
(12) Patent Application Publication
(10) Pub. No.: US 2025/0085574 A1
(43) Pub. Date: Mar. 13, 2025

(54) ELECTRO-OPTICAL MODULATOR WITH AN INTEGRATED MEMORY DEVICE

(71) Applicant: National University of Singapore, Singapore (SG)

(72) Inventors: Zefeng XU, Singapore (SG); Chun-Kuei CHEN, Singapore (SG); Hong-Lin LIN, Singapore (SG); Aaron James DANNER, Singapore (SG); Aaron Voon-Yew THEAN, Singapore (SG)

(21) Appl. No.: 18/829,364

(22) Filed: Sep. 10, 2024

(30) Foreign Application Priority Data
Sep. 12, 2023 (SG) 10202302559S

(51) Int. Cl. G02F 1/035; G02B 6/12; G02B 6/13; G02B 6/293; H10B 53/30

(52) U.S. Cl. CPC G02F 1/035; G02B 6/13; G02B 6/29338; H10B 53/30; G02B 2006/12142; G02F 2203/15

(57) ABSTRACT

This document describes an electro-optic modulator with an integrated memory device comprising a micro-ring resonator and the memory device comprising a ferroelectric capacitor disposed in a partial circumference of a raised ring waveguide of the micro-ring resonator. An electric field is generated between transparent electrodes of the ferroelectric capacitor when a voltage is applied between these two layers, whereby the electric filed causes a polarization state of the ferroelectric capacitor to change based on the strength of the electric field. The electric field then extends between the ferroelectric capacitor and a bottom electrode layer of the micro-ring resonator when the applied voltage is removed, causing a refractive index of a non-centrosymmetric material of the micro-ring resonator to change based on the strength of the extended electric field.

### CROSS-REFERENCE TO RELATED APPLICATION

This application claims the benefit of priority to Singapore patent application no. 10202302559S which was filed on 12 Sep. 2023, the contents of which are hereby incorporated by reference in its entirety for all purposes.

### TECHNICAL FIELD

This application relates to an electro-optic modulator with an integrated memory device. The electro-optic modulator comprises a micro-ring resonator and a ferroelectric capacitor that is disposed on a partial circumference of a raised ring waveguide of the micro-ring resonator.

### BACKGROUND

Electro-optic modulators are widely used to modulate optical signals using electrical signals. As such, electro-optic modulators (EOMs) are becoming increasingly vital components in high-speed telecommunications and a variety of emerging technologies, such as optical sensors, photonic neural networks, quantum information processing, and in future applications such as inter-chiplet optical interconnect networks via photonic interposers. EOMs function by modulating the phase, amplitude, or polarization of optical signals in response to an electrical signal, enabling rapid and efficient data transmission, especially in telecommunication systems, where EOMs modulate light in fiber optic networks to facilitate high-speed internet and communication systems. Beyond their use in telecommunication systems, EOMs are also utilized to enhance the sensitivity and accuracy of optical sensors and in enabling the processing of information at the speed of light in photonic neural networks, significantly improving computational efficiency. They also play a pivotal role in quantum information processing, where precise control of light is necessary for manipulating quantum states. The performance, power efficiency, functionality, and integration of EOMs are crucial metrics driving innovations aimed at advancing these technological systems.

However, EOMs comprising lithium niobate on insulator (LNOI) modulators that utilize thermo-optical (TO) or carrier-based electro-optic (EO) modulation methods, such as accumulation, depletion, and injection, face significant drawbacks including high power consumption, substantial insertion loss (i.e., due to free-carrier absorption), and switching latency caused by large-device parasitic. These limitations affect the efficiency and performance of such modulators, particularly in high-speed and low-power applications, necessitating the development of alternative approaches or improved designs to address these challenges.

Additionally, the realization of electro-optic memories has posed a significant challenge to those skilled in the art. In the absence of a high-density native photonic memory solution, photonic computing systems must continuously transfer data between electronic memories and photonic components, resulting in considerable energy costs that adversely affect the power-performance metrics of systems like photonic neural networks. As such, those skilled in the art are constantly looking for solutions to optimize the efficiency and performance of advanced photonic systems by adopting innovative means to reduce the energy overhead and to enhance the overall functionality of photonic computing architectures.

### SUMMARY

In one aspect, the present disclosure describes an electro-optic modulator with an integrated memory device comprising a micro-ring resonator and a ferroelectric capacitor disposed on a partial circumference of a raised ring waveguide of the micro-ring resonator. The micro-ring resonator comprises a substrate, an electrode layer disposed on the substrate, a dielectric layer disposed on the electrode layer and a raised ring waveguide disposed on the dielectric layer, wherein the raised ring waveguide comprises a non-centrosymmetric material. As for the ferroelectric capacitor, the capacitor comprises a first transparent electrode disposed on the raised ring waveguide, a ferroelectric layer disposed on the first transparent electrode, and a second transparent electrode disposed on the ferroelectric layer such that the ferroelectric layer is interposed between the first and the second transparent electrodes. When a first voltage is being applied between the electrode layer and the first transparent electrode, a first electric field is generated between the electrode layer and the first transparent electrode and the first electric field causes a refractive index of the non-centrosymmetric material to change based on a strength of the first electric field. Additionally, the first electric field is also coupled to the ferroelectric layer of the ferroelectric capacitor by the first transparent electrode to cause a polarization state of the ferroelectric layer to change based on the strength of the first electric field.

In a further embodiment of this aspect, when a second voltage is being applied between the first and the second transparent electrodes, a second electric field is generated between the first and the second transparent electrodes and the second electric field is then coupled to the non-centrosymmetric material of the raised ring waveguide by the first transparent electrode to cause the refractive index of the non-centrosymmetric material to change based on a combined strength of the coupled second electric field and the first electric field.

In yet a further embodiment of this aspect, the present disclosure describes an electro-optic modulator that further comprises a resistive heating element that is disposed on a non-raised portion of the raised ring waveguide such that the resistive heating element is adjacent to an inner circumference of the raised ring waveguide of the micro-ring resonator. When a current is being passed through the resistive heating element, this causes heat to be generated in the resistive heating element and this heat is then conducted to the non-centrosymmetric material of the raised ring waveguide to cause the refractive index of the non-centrosymmetric material to change based on a temperature gradient across the non-centrosymmetric material.

In another aspect, the present disclosure describes a method for forming an electro-optic modulator with an integrated memory device, the method comprising the steps of forming a micro-ring resonator and forming a ferroelectric capacitor on a partial circumference of the raised ring waveguide of the micro-ring resonator. The forming of the micro-ring resonator comprising the steps of depositing a substrate, forming an electrode layer on the substrate, forming a dielectric layer on the electrode layer, and forming a raised ring waveguide on the dielectric layer, wherein the raised ring waveguide comprises a non-centrosymmetric material. The forming of the ferroelectric capacitor comprises the steps of forming a first transparent electrode on the raised ring waveguide, forming a ferroelectric layer on the first transparent electrode, and forming a second transparent electrode on the ferroelectric layer such that the ferroelectric layer is interposed between the first and the second transparent electrodes. In this aspect, a first electric field is generated between the electrode layer and the first transparent electrode in response to a first voltage being applied between the electrode layer and the first transparent electrode, wherein the first electric field causes a refractive index of the non-centrosymmetric material to change based on a strength of the first electric field, and wherein the first electric field is coupled to the ferroelectric layer of the ferroelectric capacitor by the first transparent electrode to cause a polarization state of the ferroelectric layer to change based on the strength of the first electric field.

In another embodiment of this aspect, the present disclosure describes a method for forming an electro-optic modulator that further comprises the step of forming a resistive heating element on a non-raised portion of the raised ring waveguide such that the resistive heating element is formed adjacent to an inner circumference of the raised ring waveguide of the micro-ring resonator.

### BRIEF DESCRIPTION OF THE DRAWINGS

Various embodiments of the present disclosure are described below with reference to the following drawings:

FIG. 1 illustrates a perspective view of an electro-optical modulator with an integrated memory device in accordance with an embodiment of the present disclosure;

FIG. 2 illustrates a top view of an electro-optical modulator with an integrated memory device in accordance with an embodiment of the present disclosure;

FIG. 3 illustrates another top view of an electro-optical modulator with an integrated memory device in accordance with an embodiment of the present disclosure;

FIG. 4 illustrates a cross-sectional view of a part of the electro-optical modulator with an integrated memory device across an x-y plane in accordance with embodiments of the present disclosure;

FIG. 5 illustrates a cross-sectional view of the overall electro-optical modulator with an integrated memory device across an x-y plane in accordance with embodiments of the present disclosure;

FIG. 6 illustrates an enlarged cross-sectional view of a raised ring waveguide of the micro-ring resonator with the integrated memory device across an x-y plane in accordance with embodiments of the present disclosure;

FIG. 7 illustrates a perspective view of another embodiment of the electro-optical modulator with an integrated memory device and an integrated resistive heating element in accordance with an embodiment of the present disclosure;

FIG. 8 illustrates a top view of another embodiment of the electro-optical modulator with an integrated memory device and an integrated resistive heating element;

FIG. 9 illustrates a cross-sectional view of the overall electro-optical modulator with an integrated memory device and an integrated resistive heating element across an x-y plane in accordance with embodiments of the present disclosure;

FIG. 10 illustrates a flowchart of a process to form an electro-optical modulator with an integrated memory device in accordance with an embodiment of the present disclosure;

FIG. 11(a) illustrates a simulated phase-matched modal profile of a transverse electric (TE) mode in a lithium niobate on insulator ridge waveguide;

FIG. 11(b) illustrates a simulated phase-matched modal profile of a transverse magnetic (TM) mode in a lithium niobate on insulator ridge waveguide;

FIG. 12(a) illustrates gap and edge coupling efficiencies as a function of patterned gap and taper widths;

FIG. 12(b) illustrates the variation in propagation loss of the waveguide in TE and TM modes when the waveguide length is varied;

FIG. 13(a) illustrates the relationship between the ferroelectric polarization of a hafnium zirconium oxide (HZO) capacitor and an applied electric field;

FIG. 13(b) illustrates the variation in the ferroelectric polarization of the HZO capacitor over a number of cycles when the capacitor is operated under an operating condition of P/E: 3.125 MV/cm at 1 μs;

FIG. 13(c) illustrates the variation in the ferroelectric polarization of the HZO capacitor over a number of cycles when the capacitor is operated under an operating condition of P/E: 3.125 MV/cm at 10 μs with sketches on the imprint polarization direction and crystal cell structure being shown in the inset of this figure;

FIG. 13(d) illustrates the variation in the transmission spectrum of the electro-optic modulator when the wavelength of the received optical signal is varied when the Q-factor of the modulator is set at 1.6×10⁴;

FIG. 13(e) illustrates the shift in the transmission spectrum of the electro-optic modulator when the HZO capacitor is polarized, when a voltage is applied to the electro-optic modulator and when current is applied to the resistive heating element;

FIG. 14(a) illustrates the shift in the resonance of the micro-ring resonator of the electro-optic modulator due to non-volatile ferroelectric polarization of the HZO capacitor, electro-optic modulation and thermal optic modulation; and

FIG. 14(b) illustrates the variation in the ferroelectric polarization loss of the electro-optic modulator when environmental temperature is varied and when an electric field of 4 MV/cm is present in the electro-optic modulator.

### DETAILED DESCRIPTION

The following detailed description is made with reference to the accompanying drawings, showing details and embodiments of the present disclosure for the purposes of illustration. Features that are described in the context of an embodiment may correspondingly be applicable to the same or similar features in the other embodiments, even if not explicitly described in these other embodiments. Additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance as generally understood in the relevant technical field, e.g., within 10% of the specified value.

As used herein, the term “and/or” includes any and all combinations of one or more of the associated listed items.

As used herein, “comprising” means including, but not limited to, whatever follows the word “comprising”. Thus, use of the term “comprising” indicates that the listed elements are required or mandatory, but that other elements are optional and may or may not be present.

As used herein, “consisting of” means including, and limited to, whatever follows the phrase “consisting of”. Thus, use of the phrase “consisting of” indicates that the listed elements are required or mandatory, and that no other elements may be present.

In the context of various embodiments, the term “surround” means to enclose something completely to form a barrier around it. Thus, the use of the term “surround” indicates that something is on all sides of another thing.

In the context of various embodiments, the term “disposed on” relates to the placement or deposition of one material or layer onto the surface of another and may involve one or more types of deposition techniques.

In the context of various embodiments, the term “around” or “adjacent” means to be in the proximity or location of something and does not necessarily mean that two objects have to be in contact.

In the context of various embodiments, the directional terms mentioned herein, such as “above” and “below” or “upper” and “lower” refer to directions as described with reference to the drawings. Therefore, the directional terms are only used for illustration and are not meant to limit the present disclosure.

It should be noted that although the terms first, second and third are used herein to describe various elements, these elements should not be limited by these terms as these terms are meant to only distinguish one element from another element. Thus, the first element described herein could be termed as a second element without departing from this disclosure.

As used herein, a “layer” refers to a material portion including a region having a particular thickness. The layer may extend over the entirety of the structure or may cover only part of the structure as defined in the description. For example, a layer may be located between two horizontal planes; may be located between, or at, a top surface and a bottom surface of the structure. The layer may also extend horizontally, vertically, and/or along the surface of the structure.

Additionally, for the sake of brevity, extensive explanations of conventional techniques of fabricating semiconductor devices and integrated circuits are not described in detail herein. The tasks and processes described herein may also be integrated into a more comprehensive procedure with extra steps of features that are not elaborated upon in this document. Specifically, certain processes of fabricating semiconductor devices are well known to one skilled in the art hence, such processes will be omitted entirely.

An electro-optic modulator (EOM) is a device that modulates the properties of light, such as its phase, amplitude, or polarization, using an electric field. This modulation is primarily achieved through the electro-optic effect, where the refractive index of an electro-optic material (e.g., lithium niobate) changes in response to an applied electric field. EOMs are usually constructed with a waveguide made from an electro-optic material and are also provided with electrodes that cause an electric field to be formed across the waveguide when a voltage is applied to these electrodes. As the applied electric field induces a change in the refractive index of the material, an optical signal propagating through the waveguide will then be modulated accordingly.

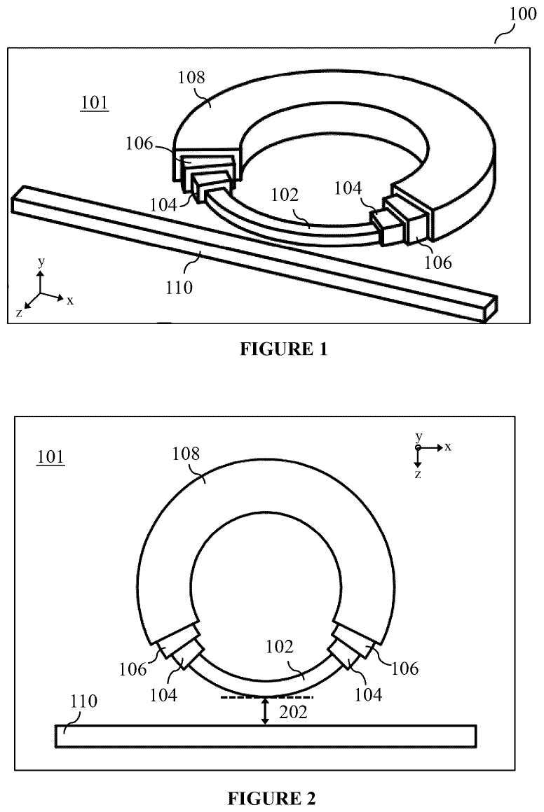

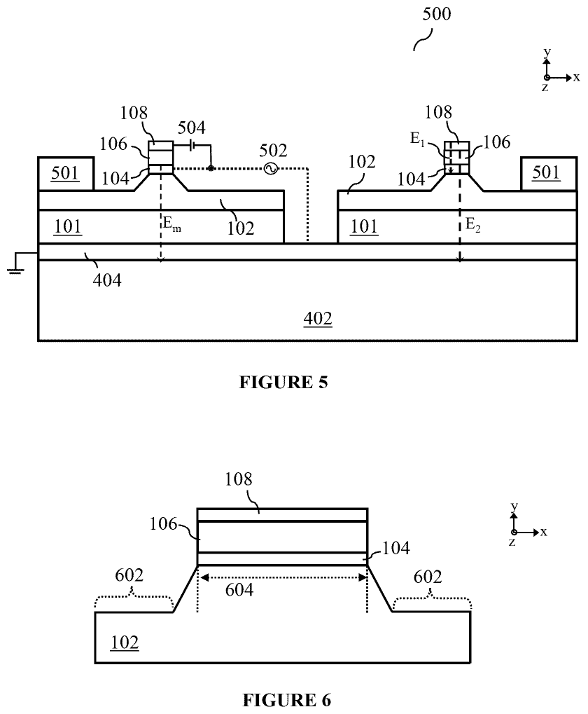

A perspective view of an electro-optic modulator with an integrated memory (EOMM) device in accordance with an embodiment of the present disclosure is illustrated in FIG. 1. As illustrated, EOMM device 100 comprises a micro-ring resonator and a ferroelectric capacitor which acts as a non-volatile memory. The micro-ring resonator comprises raised ring waveguide 102 and bus waveguide 110 that are both disposed on dielectric layer 101. Bus waveguide 110 is provided adjacent a part of an outer circumference of raised ring waveguide 102 such that optical signals may be coupled into and out of raised ring waveguide 102 via bus waveguide 110. It should be noted that although it is not shown in FIG. 1, dielectric layer 101 is formed on a bottom electrode layer which in turn is disposed on a substrate. These layers are illustrated in the cross-sectional view of EOMM device 100 as illustrated in FIGS. 4 and 5.

With reference to FIG. 1, it can be seen that the ferroelectric capacitor comprises transparent electrode 104 (i.e., a first transparent electrode) that is disposed on raised ring waveguide 102, ferroelectric layer 106 that is disposed on transparent electrode 104, and transparent electrode 108 (i.e., a second transparent electrode) that is disposed on ferroelectric layer 106 such that ferroelectric layer 106 is interposed or sandwiched between the transparent electrode layers 104 and 108.

It can be seen that the ferroelectric capacitor is only disposed on or only covers a partial circumference of raised ring waveguide 102 of the micro-ring resonator. One skilled in the art will recognize that the extent to which the ferroelectric capacitor overlaps or covers raised ring waveguide 102 is not limited to the illustration in FIG. 1. In embodiments of the disclosure, the ferroelectric capacitor may cover almost the entire circumference of raised ring waveguide 102 except for the coupling area between raised ring waveguide 102 and bus waveguide 110.

In embodiments of the disclosure, except for the coupling area between raised ring waveguide 102 and bus waveguide 110, transparent electrode 104 may be formed on all surfaces of raised ring waveguide 102 which are not in contact with dielectric layer 101. Similarly, ferroelectric layer 106 may be formed on the surfaces of transparent electrode 104 such that it largely follows the profile of transparent electrode 104. Transparent electrode 108 may then be formed on the surfaces of ferroelectric 106 such that it then largely follows the profile of ferroelectric layer 106.

FIG. 2 illustrates a top view of EOMM device 100 along the x-z plane in accordance with an embodiment of the present disclosure. It can be seen that a coupling gap 202 exists in a coupling region between raised ring waveguide 102 and bus waveguide 110. Coupling gap 202 between bus waveguide 110 and raised ring waveguide 102 is used to determine the strength of the evanescent coupling between these two waveguides.

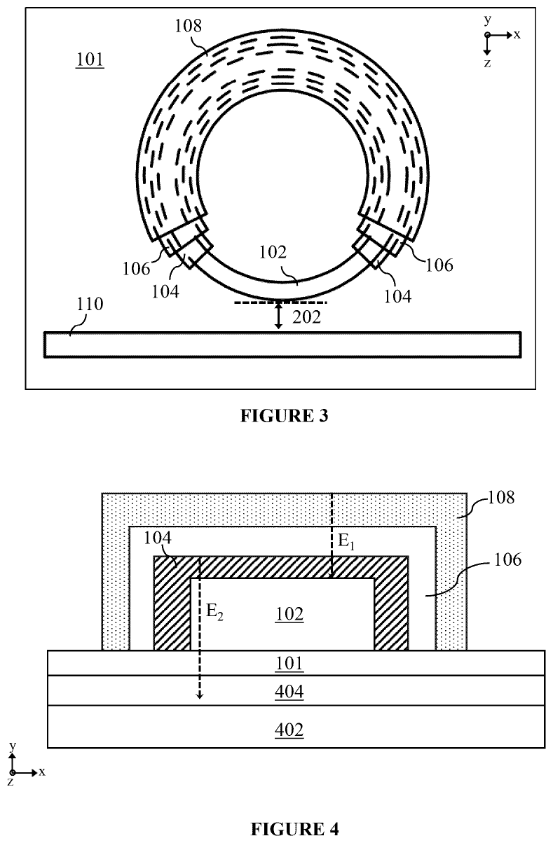

FIG. 3 illustrates a top view of EOMM device 100 along the x-z plane in accordance with an embodiment of the present disclosure where transparent electrodes 104 and 108, and ferroelectric layer 106 are illustrated as dotted lines such that the overlapping arrangement of these layers over raised ring waveguide 102 can be clearly seen. Although FIGS. 1, 2 and 3 show that the ends of transparent electrode 104 extend beyond ferroelectric layer 106, and that the ends of ferroelectric layer 106 extend beyond transparent electrode 108, one skilled in the art will recognize that these “extensions” are for illustration purposes only, so that the inner layers of the ferroelectric capacitor can be clearly seen and described in this disclosure. In embodiments of the disclosure, the endings of transparent electrodes 104 and 108, and ferroelectric layer 106 may all be aligned to each other such that a uniform electric field may be formed across ferroelectric layer 106 when a voltage is applied between transparent electrodes 104 and 108.

A cross-sectional view of a part of EOMM device 100 along the y-x plane is illustrated in FIG. 4. Bottom electrode layer 404 is disposed on substrate 402. In embodiments of the disclosure, substrate 402 may comprise, but is not limited to, silicon, silicon dioxide, silicon nitride, etc., while bottom electrode layer 404 may comprise any conductive material such as gold, platinum, aluminum, etc. Dielectric layer 101 which is disposed on bottom electrode layer 404, may comprise of any insulating materials such as silicon dioxide, silicon nitride, etc.

In embodiments of the disclosure, raised ring waveguide 102 may be disposed on dielectric layer 101 as illustrated in FIG. 4. Raised ring waveguide 102 may comprise a non-centrosymmetric material such as, but is not limited to, lithium niobate, potassium dihydrogen phosphate, gallium arsenide or barium titanate or any other type of material whose refractive index may change linearly when an electric field is applied and/or when a temperature change occurs across the material. In embodiments of the disclosure, transparent electrode 104 may be disposed on all three surfaces of raised ring waveguide 102 which are not in contact with dielectric layer 101, i.e., the surfaces on the two y-z planes, and the z-x plane. Similarly, ferroelectric layer 106 may be formed on the surfaces of transparent electrode 104 such that it largely follows the profile of transparent electrode 104. Transparent electrode 108 may then be formed on the surfaces of ferroelectric layer 106 such that it then largely follows the profile of ferroelectric layer 106. In embodiments of the disclosure, transparent electrodes 104 and 108 may comprise indium tin oxide or any other types of similar material while ferroelectric layer 106 may comprise hafnium zirconium oxide, barium titanate, lead zirconate titanate, etc. or any other materials whose polarization may be altered to be aligned with an electric field when the electric field is applied across the material. Transparent electrodes 108 are preferred over regular opaque electrodes as such electrodes have a lower refractive index, which results in lower optical losses in contrast with the optical losses of opaque electrodes.

In a first embodiment of the disclosure, when a voltage is applied between transparent electrode 104 and transparent electrode 108 (e.g., illustrated as voltage 504 in FIG. 5), and when bottom electrode layer 404 is connected to a ground plane, an electric field E₁ will be formed between these two electrodes, i.e., across the cross section of ferroelectric layer 106, causing a polarization state of ferroelectric layer 106 to change and to be set based on the strength of the electric field E₁.

When the voltage applied between transparent electrodes 104 and 108 is removed, the polarization state of ferroelectric layer 106 remains unchanged due to its non-volatile nature. This persistent polarization of ferroelectric layer 106 causes the electric field E₁ to extend to form extended electric field E₂, which is formed between polarized ferroelectric layer 106 and grounded bottom electrode layer 404. It is useful to note that the electric field strength of E₂ is weaker compared to that of E₁.

The electric field E₂ extends across raised ring waveguide 102, causing the refractive index of the waveguide material of raised ring waveguide 102 to change according to the strength of extended electric field E₂, and this occurs due to the Pockels effect. This change in refractive index modulates the optical signal passing through raised ring waveguide 102. Subsequently, when a new voltage level is applied between transparent electrodes 104 and 108, a new electric field will then form between these two transparent electrodes causing a new state (or data) to be written to the ferroelectric capacitor. A new modulation state can then be applied to the optical signal in raised ring resonator 102 when the new voltage level is removed and as the new electric field extends from ferroelectric layer 106 to bottom electrode layer 404.

In other words, when a voltage is applied between transparent electrodes 104 and 108 and when bottom electrode layer 404 is grounded, an electric field is generated that influences the memory function of ferroelectric layer 106 (of the ferroelectric capacitor). The electric field then extends between the ferroelectric capacitor and bottom electrode layer 404, across raised ring waveguide 102, when the applied voltage is removed. This extended electric field influences the refractive index of raised ring waveguide 102 thereby modulating an optical signal propagating through raised ring waveguide 102 via the electro-optic effect. Additionally, as the refractive indexes of indium tin oxide (n=1.5), which is the material used for the transparent electrodes, and hafnium zirconium oxide (n=1.9), which is the material used for the ferroelectric layer, are both lower than lithium niobate (n=2.2), which is the material of the raised ring waveguide, in C-band and O-band modes of operation, these material layers can be easily co-integrated on the raised ring waveguide, without significant optical loss.

FIG. 5 illustrates a cross-sectional view across an x-y plane of another embodiment of the electro-optical modulator with an integrated memory (EOMM) device while FIG. 6 illustrates an enlarged cross-sectional view across an x-y plane of the ferroelectric capacitor and the raised ring waveguide illustrated in FIG. 5. Unlike the embodiment illustrated in FIG. 4, EOMM device 500 illustrated in FIGS. 5 and 6 have a raised ring waveguide 102 that comprises a non-raised portion 602 and a raised portion 604 (see FIG. 6) whereby a tapered projection of raised ring waveguide 102 that forms the ring-like structure has a base that is wider than raised portion 604 of the projection. In embodiments of the disclosure, raised ring waveguide 102 may be disposed on dielectric layer 101 while transparent electrode 104 may be disposed only on raised portion 604 of raised ring waveguide 102. Ferroelectric layer 106 may then be disposed on the surface of transparent electrode 104 and transparent electrode 108 may be disposed on the surface of ferroelectric layer 106—forming the structure shown in FIG. 6. EOMM device 500 is also provided with cladding 501 that may be disposed on non-raised portion 602 of raised ring waveguide 102 whereby cladding 501 may comprise air or Silicon Dioxide. In embodiments of the disclosure, cladding 501 may be formed over the exposed surfaces of raised ring waveguide 102 (not shown) and the coverage of cladding 501 over the micro-ring resonator and the ferroelectric capacitor is left as a design choice to one skilled in the art.

Similar to the operation of EOMM device 100, when voltage 504 is applied between transparent electrodes 104 and 108, an electric field E₁ is generated that alters the polarization state of ferroelectric layer 106. When voltage 504 is removed, the electric field E₂ then extends to bottom electrode layer 404, across raised ring waveguide 102, influencing the refractive index of raised ring waveguide 102.

In a further aspect of this embodiment, instead of applying voltage 504 between transparent electrode 104 and 108, voltage 502 may instead be applied between transparent electrode 104 and bottom electrode layer 404. This causes an electric field Eₘ to be formed between transparent electrode 104 and bottom electrode layer 404, across raised ring waveguide 102. Electric field Eₘ then causes the refractive index of the non-centrosymmetric material of raised ring waveguide 102 to change based on the strength of electric field Eₘ. The change in the refractive index of this non-centrosymmetric material causes the optical signal propagating through raised ring waveguide 102 to then be modulated accordingly

In yet another aspect of this embodiment, voltage 504 may be first applied between transparent electrodes 104 and 108. Electric field E₁ forms across these transparent electrodes, setting the polarization state of the ferroelectric capacitor. After voltage 504 is removed, electric field E₁ extends from ferroelectric layer 106 of the ferroelectric capacitor to bottom electrode layer 404, forming extended electric field E₂. The refractive index of raised ring waveguide 102 is then altered according to the strength of electric field E₂. Voltage 502 may then be applied between transparent electrode 104 and bottom electrode layer 404, causing a combination of electric fields E₂ and Eₘ to be formed across raised ring waveguide 102. The refractive index of raised ring waveguide 102 is then changed according to the combination of these two electric fields, and this in turn causes an optical signal propagating through raised ring waveguide 102 to be modulated accordingly.

In embodiments of the disclosure, the thickness of transparent electrodes 104 and 108 may be adjusted to optimize the performance of EOMM device 500. As electric field Eᵣ indirectly couples to the non-centrosymmetric material of raised ring waveguide 102, this indirectly coupled electric field Eₒ will weaken when the thickness of transparent electrodes 104 and 108 increases. However, if the thickness of transparent electrodes 104 and 108 are reduced too much, this will cause the resistivity of these electrodes to increase which in turn causes the driving voltage and R-C latency of the ferroelectric capacitor to increase as well. Hence, as a trade-off, when transparent electrodes 104 and 108 comprise an indium tin oxide material, the thickness of transparent electrodes 104 and/or 108 is set to be between 5.5 nm and 6.5 nm, preferably at 6.0 nm.

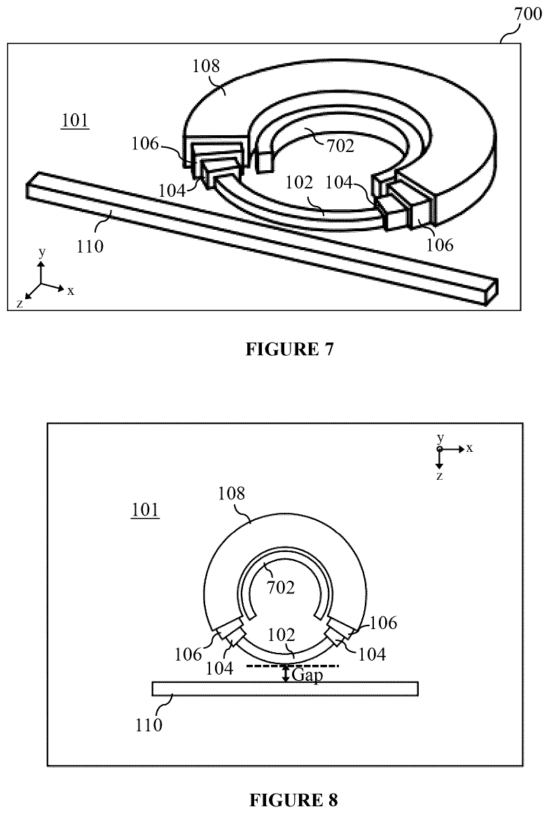

A second embodiment of the electro-optical modulator with an integrated memory device is illustrated in FIG. 7. FIG. 7 illustrates a perspective view of EOMM device 700 having integrated resistive heating element 702. The operation of EOMM device 700 is generally the same as the operation of EOMM device 500 with the addition of resistive heating element 702 being disposed on a non-raised portion (not shown) of raised ring waveguide 102 such that resistive heating element 702 is adjacent to an inner circumference of raised ring waveguide 102 of the micro-ring resonator of EOMM device 700. FIG. 8 illustrates a top view of EOMM device 700 along the x-z plane in accordance with an embodiment of the present disclosure. It can be seen that resistive heating element 702 is configured to be adjacent to an inner circumference of raised ring waveguide 102 of the micro-ring resonator of EOMM device 700 such that when a current is provided to resistive heating element 702, element 702 will increase in temperature and this heat will be conducted to the non-centrosymmetric material of raised ring waveguide 102 to cause a temperature of the non-centrosymmetric material to change whereby the refractive index of the non-centrosymmetric material then changes based on the change in the temperature of the non-centrosymmetric material.

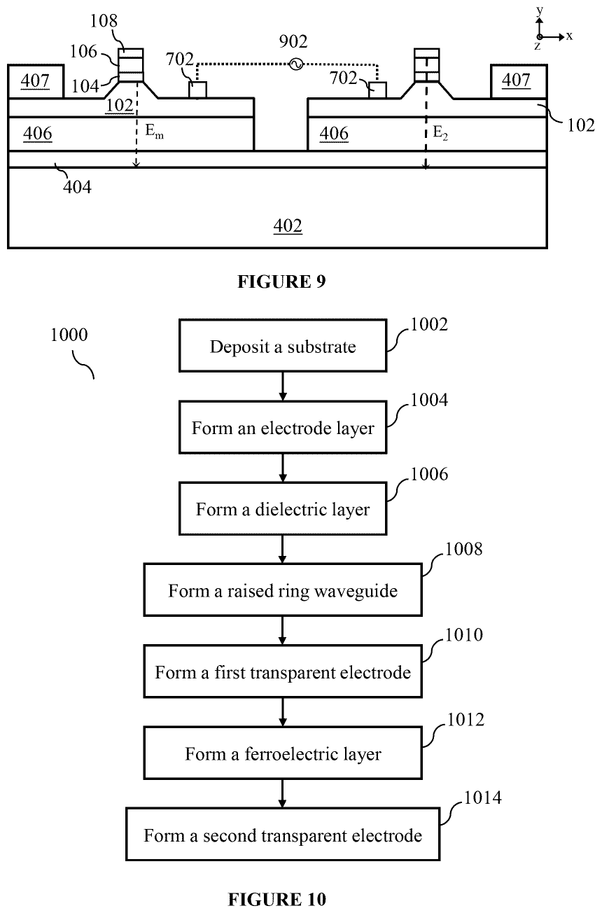

FIG. 9 illustrates a cross-sectional view across an x-y plane of the second embodiment of the electro-optical modulator with an integrated memory device as illustrated in FIG. 7. When current 902 is provided to resistive heating element 702, element 702 will increase in temperature and the heat generated by element 702 will be conducted to the non-centrosymmetric material of raised ring waveguide 102, in particular to the raised portion of raised ring waveguide 102 to cause a temperature of the non-centrosymmetric material to change. When this happens, the refractive index of the non-centrosymmetric material then changes based on the temperature change in this material, i.e., due to the thermo-optic effect.

In further embodiments of the disclosure, in addition to the addition and removal of voltage 504, followed by the sequential addition of voltage 502 (as shown in FIG. 5) to EOMM device 700, current 902 as shown in FIG. 9 may also be then sequentially provided to resistive heating element 702 such that the refractive index of the non-centrosymmetric material of raised ring waveguide 102 changes based on a combined strength of electric fields E₂ and Eₘ and the heat as generated by resistive heating element 702 thereby achieving combined electro-optic and thermo-optic modulation in raised ring waveguide 102. This complementary integration allows the device to operate at higher-speed data transmission, up to terra bits per second, while circumventing the relatively slower switched speed of non-volatile ferroelectric memories.

A process for fabricating an electro-optic modulator with an integrated memory (EOMM) device in accordance with an embodiment of this disclosure is illustrated in FIG. 10. Process 1000 may be performed using standard semiconductor fabrication or manufacturing steps. At step 1002, a micro-ring resonator is first formed whereby process 1000 first deposits a substrate. Once this is done, process 1000 then forms an electrode layer on the substrate at step 1004. Process 1000 then forms a dielectric layer on the electrode layer at step 1006. A raised ring waveguide is then formed on the dielectric layer by process 1000 at step 1008, wherein the raised ring waveguide comprises a non-centrosymmetric material. Once the micro-ring resonator has been formed, process 1000 then proceeds to form a ferroelectric capacitor on a partial circumference of the raised ring waveguide of the micro-ring resonator. At step 1010, process 1000 forms a first transparent electrode on the raised ring waveguide. Process 1000 then forms a ferroelectric layer on the first transparent electrode at step 1012 and proceeds to form a second transparent electrode on the ferroelectric layer at step 1014 such that the ferroelectric layer is interposed between the first and the second transparent electrodes.

After the EOMM device is formed, a first electric field may then be generated between the ferroelectric layer sandwiched between the first and second transparent electrodes when a first voltage is applied between these two transparent electrodes. This causes a polarization state of the ferroelectric layer to change based on the strength of the first electric field. After the first voltage is removed, the polarization state of the ferroelectric layer remains unchanged, and the first electric field then extends to a bottom electrode layer of the raised ring waveguide, causing a refractive index of the non-centrosymmetric material of the raised ring waveguide to change based on a strength of the extended electric field.

In further embodiments of the disclosure, a resistive heating element is formed on a non-raised portion of the raised ring waveguide such that the resistive heating element is formed adjacent to an inner circumference of the raised ring waveguide of the micro-ring resonator. In a still further embodiment of the disclosure, a bus waveguide is formed adjacent a part of an outer circumference of the raised ring waveguide of the micro-ring resonator that is not disposed with the ferroelectric capacitor, wherein the bus waveguide and the part of the outer circumference of the raised ring waveguide have a coupling gap between 400 nm and 500 nm.

In embodiments of the disclosure, an electro-optic modulator with an integrated memory (EOMM) device in accordance with an embodiment of this disclosure may be fabricated as follows.

A micro-ring resonator comprising a substrate with an electrode layer formed on the substrate, a dielectric layer formed on the electrode layer, and a raised ring waveguide formed on the dielectric layer is first fabricated using known semiconductor fabrication techniques. In this embodiment, the raised ring waveguide comprising a lithium niobate (LN) material first undergoes micro-ring resonator patterning using photolithography and etching techniques to define the structure of the micro-ring. The patterned LN surface is then treated with a piranha solution (i.e., a mixture of sulfuric acid and hydrogen peroxide) to clean the patterned LN surface.

A thick layer of silicon dioxide of about 1 μm thickness is then deposited on the LN surface to act as a cladding layer on the micro-ring resonator. Openings or windows are then etched in the silicon dioxide layer to expose areas where electrodes and other components are to be formed. A thin layer of approximately 6 nm of indium tin oxide is then deposited on the raised ring waveguide using sputtering techniques to form the first transparent electrode. About an 8 nm thickness of hafnium zirconium oxide is then grown on the first transparent electrode using Atomic Layer Deposition (ALD) at a temperature of 280° C. This forms the ferroelectric layer. A layer of tungsten is then sputtered on the ferroelectric layer to act as a ferro-induction layer. This layer functions helps to induce the ferroelectric properties of the ferroelectric layer. The resulting structure is then annealed in an oxygen environment at 380° C. to improve the crystallinity and ferroelectric properties of the ferroelectric layer. Once annealed, the tungsten layer is then removed, leaving behind the ferroelectric layer and the first transparent electrode. Another layer of indium tin oxide is then sputtered on the ferroelectric layer to form a second transparent electrode having a thickness of around 10 nm. The completed wafer is then diced into individual devices and focused ion beam (FIB) polishing is then used to smooth and refine the edges and surfaces of the structures, particularly at the coupling regions.

### Simulation Results

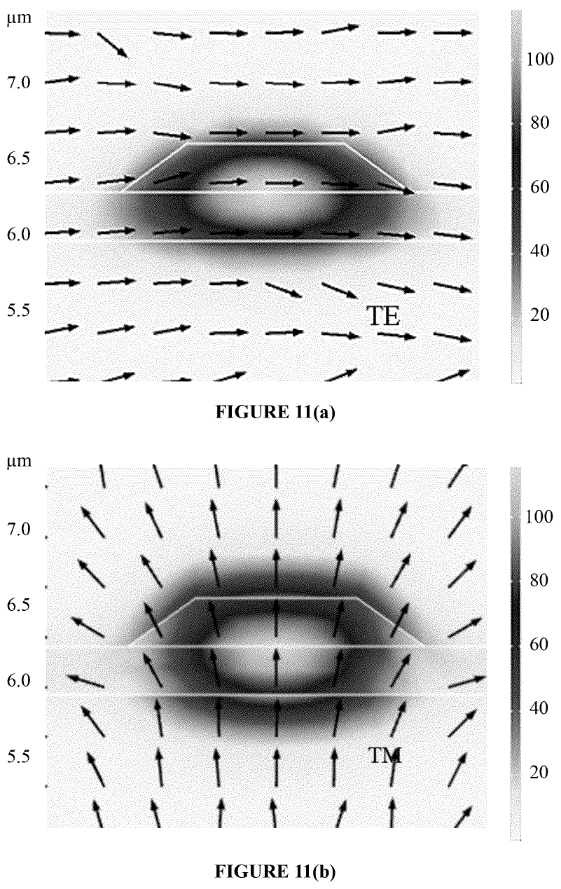

A single mode LN waveguide is fabricated based on some of the steps as described above, and the simulated phase-matched modal profiles of the Transverse Electric (TE) and Transverse Magnetic (TM) modes in the waveguide are illustrated in FIGS. 11(a) and 11(b). The profiles illustrated in these figures show how the electric fields are distributed within the waveguide for each of these TE and TM modes. The propagation loss of the waveguide is evaluated at 0.58 dB/mm and 0.70 dB/mm in TE and TM modes respectively.

For completeness, it should be noted that the simulation setup comprises an Amplified Spontaneous Emission (ASE) source that is configured to provide a broad-spectrum light source, which is then passed through a Linear Polarizer (LP) to select the desired polarization state (TE or TM). A Polarization Controller (PC) is then used to finely adjust the polarization of the light before the polarized light enters the waveguide. The light signal is then directed through a Non-Volatile Switch (NVC) to the optical measurement instruments. The output light from the raised ring waveguide is subsequently analyzed using an Optical Spectrum Analyzer (OSA), which measures the spectral characteristics and intensity of the output light. Additionally, a Semiconductor Parameter Analyzer (SPA) might be employed to monitor electrical parameters of the EOMM device.

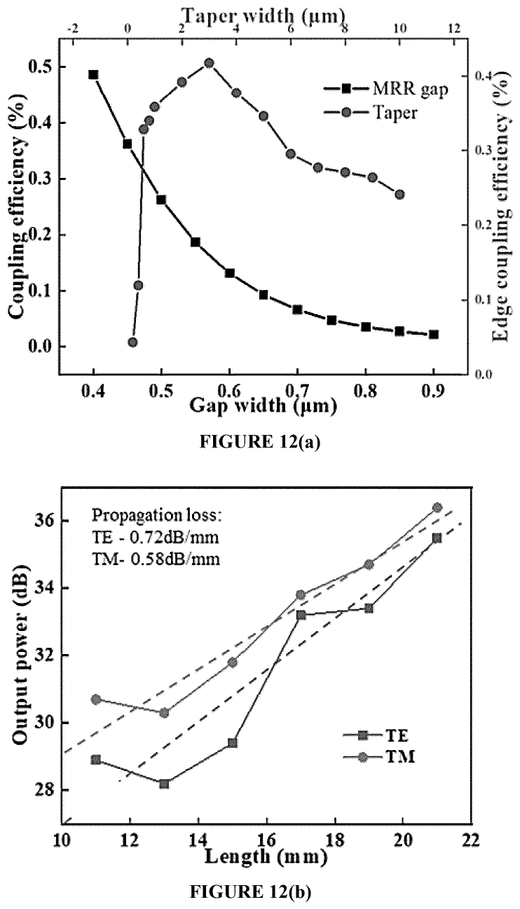

From the simulations for the single mode LN waveguide, it was observed that the coupling efficiencies between two of such waveguides, which determine how effectively light is transferred between the waveguide and external components, vary with different patterned widths for both gap and edge couplings (as shown in FIG. 12(a)). Due to the impact of the micro-loading effect (i.e., a phenomenon that affects the uniformity of etching across the wafer), it was determined that a patterned gap width between 400 nm and 500 nm, with a preferred gap width of 450 nm was preferred in this embodiment. A width within this range was chosen to ensure consistent etching results given the limitations of the adopted etching process. Additionally, to maximize the coupling efficiency of such waveguides, an optimal taper width of 3 μm of the raised portion of the waveguide was adopted. FIG. 12(b) illustrates the output power of the waveguide when the length of the waveguide is varied. From the plots in FIG. 12(b), it was found that there was a propagation loss of 0.58 dB/mm and 0.72 dB/mm in TE and TM modes respectively. These results may then be used to select a suitable gap, taper width and/or length for the arrangements in the EOMM device.

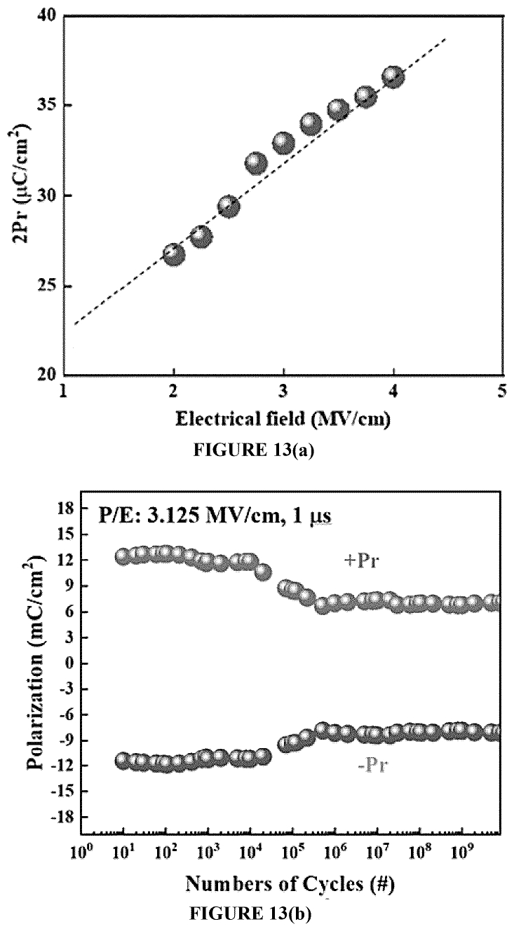

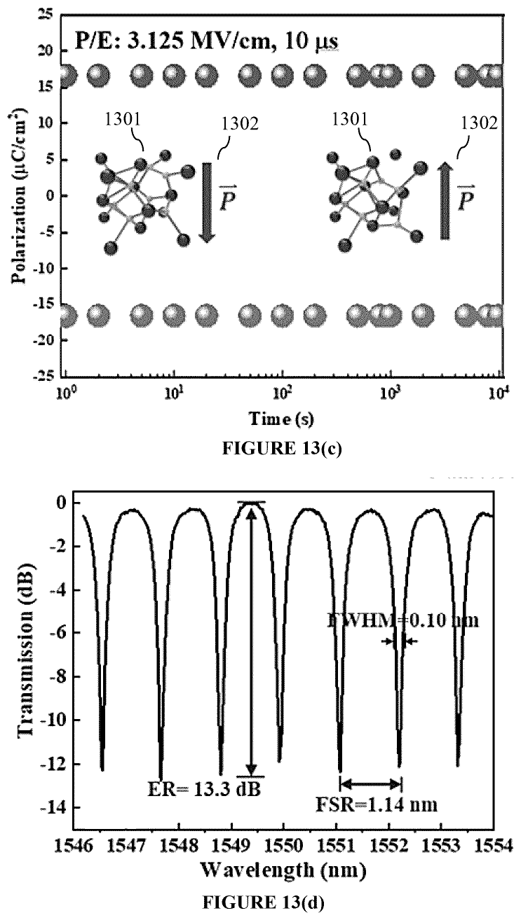

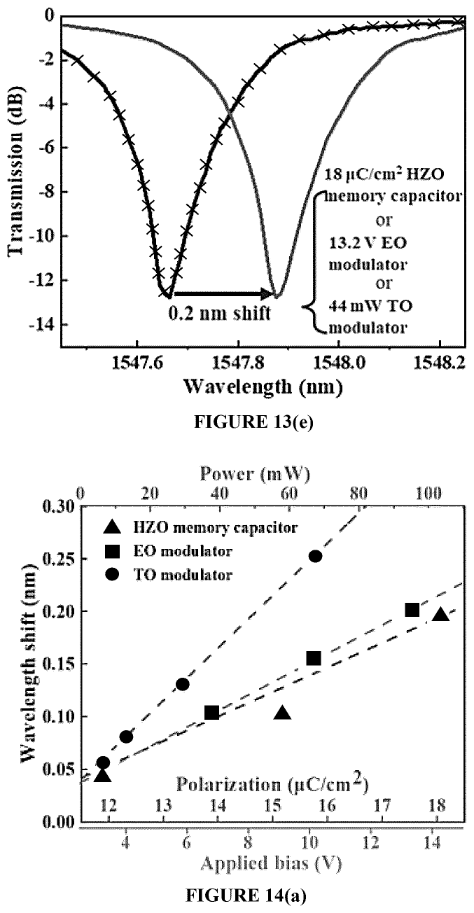

Polarization-voltage (P-V) loops were then used to characterize the performance of the ferroelectric memory capacitor of the EOMM device when the ferroelectric capacitor has a ferroelectric layer that comprises of Hafnium Zirconium Oxide (HFO). From the simulation results plotted in FIG. 13(a), it was found that both remnant polarization and coercive voltage increases as the voltage applied to the transparent electrodes increases, as shown in FIG. 13(a). Notably, the ferroelectric capacitor was able to achieve at least nine distinct switchable states within a voltage range of 2 V to 4 V, with the ferroelectric polarization demonstrating a near-linear relationship with the applied electric field.

Further, when the ferroelectric capacitor was operating at an electric field of 3.125 MV/cm, the ferroelectric capacitor was able to exhibit an endurance exceeding 10⁹ cycles, with a gradual stabilization occurring around 1 million cycles, which may be attributed to minor ferroelectric fatigue effects. This effect is illustrated in FIG. 13(b). Moreover, from the results shown in FIG. 13(c), it can be seen that the memory state retention extends well beyond 10 years, indicating long-term stability. The EOMM device itself shows excellent transmission properties, including a 13.3 dB extinction ratio (ER), a 1.14 nm free spectral range (FSR), and a 0.1 nm full width at half maximum (FWHM) and these results can be seen in FIG. 13(d). As illustrated in FIG. 13(e), the optical resonance of the EOMM device displays a wavelength shift (Δλ) of 0.2 nm in response to a ferroelectric polarization of 18 μC/cm², an applied voltage of 13.2 V (i.e., voltage 502 as shown in FIG. 5), or a heating power of 44 mW.

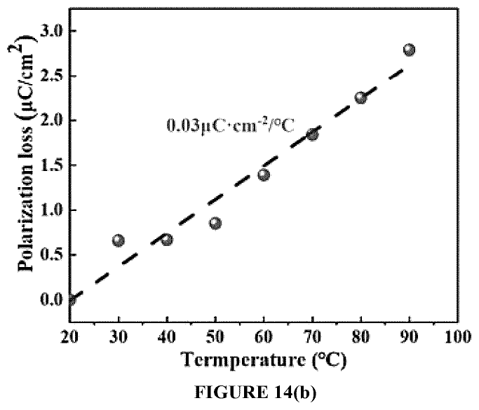

As for the tuning efficiencies of the EOMM device, this can be calculated by performing a linear fit to the relationship between the resonance shift and the applied ferroelectric polarization, voltage, and heating power, demonstrating the device's sensitivity and tunability in response to these parameters. This measurement is performed with respect to the HZO capacitor, EO modulator, and TO modulator respectively, as illustrated in FIG. 14(a), showing that the integration of HZO capacitors with micro-ring resonators to form the EOMM device showcases a promising approach for hybrid non-volatile memory and tunable photonic devices. However, it was found that the heat from the resistive current heaters (i.e., the TO modulation) may impact the stability of the ferroelectric capacitor. The relationship between the ferroelectric polarization loss that was measured at a fixed electric field of 4 MV/cm when the applied heat increases is plotted in FIG. 14(b). It can be seen that as the temperature increases, so does the polarization loss in the ferroelectric capacitor.

Numerous other changes, substitutions, variations, and modifications may be ascertained by the skilled in the art and it is intended that the present application encompass all such changes, substitutions, variations and modifications as falling within the scope of the appended claims.

1. An electro-optic modulator with an integrated memory device comprising:
a micro-ring resonator comprising:
a substrate;
an electrode layer disposed on the substrate, the electrode layer being electrically connected to a ground;
a dielectric layer disposed on the electrode layer;
a raised ring waveguide disposed on the dielectric layer, wherein the raised ring waveguide comprises a non-centrosymmetric material;
the memory device comprising a ferroelectric capacitor disposed on a partial circumference of the raised ring waveguide of the micro-ring resonator, the ferroelectric capacitor comprising:
a first transparent electrode disposed on the raised ring waveguide;
a ferroelectric layer disposed on the first transparent electrode; and
a second transparent electrode disposed on the ferroelectric layer such that the ferroelectric layer is interposed between the first and the second transparent electrodes,
wherein a first electric field is generated between the first and the second transparent electrodes in response to a first voltage being applied between the first and the second transparent electrodes, the first electric field causing a polarization state of the ferroelectric layer to change based on the strength of the first electric field,
wherein the polarization state of the ferroelectric layer remains at the changed state when the first voltage is removed, and
wherein an extended electric field is generated between the ferroelectric layer and the electrode layer in response to the first voltage being removed, the extended electric field causing a refractive index of the non-centrosymmetric material to change based on a strength of the extended electric field.

2. The electro-optic modulator according to claim 1,
wherein a second electric field is generated between the electrode layer and the first transparent electrode in response to a second voltage being applied between the first transparent electrode and the electrode layer, the second electric field causing the refractive index of the non-centrosymmetric material to change based on a combined strength of the second electric field and the first electric field.

3. The electro-optic modulator according to claim 1, further comprising:
a resistive heating element disposed on a non-raised portion of the raised ring waveguide such that the resistive heating element is adjacent to an inner circumference of the raised ring waveguide of the micro-ring resonator.

4. The electro-optic modulator according to claim 3,
wherein heat is generated in the resistive heating element in response to a current being passed through the resistive heating element, and
wherein the heat is conducted to the non-centrosymmetric material of the raised ring waveguide to cause the refractive index of the non-centrosymmetric material to change based on a change in temperature of the non-centrosymmetric material.

5. The electro-optical modulator according to claim 1, wherein the non-centrosymmetric material comprises Lithium Niobate, Potassium Dihydrogen Phosphate, Gallium Arsenide or Barium Titanate.

6. The electro-optic modulator according to claim 1, wherein the ferroelectric layer comprises Hafnium Zirconium Oxide, Barium Titanate, or Lead Zirconate Titanate.

7. The electro-optic modulator according to claim 1, wherein the first and second transparent electrodes comprise Indium Tin Oxide.

8. The electro-optic modulator according to claim 1, wherein refractive indexes of the first and second transparent electrodes and the ferroelectric layer are lower than a refractive index of the non-centrosymmetric material.

9. The electro-optic modulator according to claim 1, wherein a thickness of the first transparent electrode is between 5.5 nm and 6.5 nm.

10. The electro-optic modulator according to claim 1 further comprising:
a bus waveguide provided adjacent a part of an outer circumference of the raised ring waveguide of the micro-ring resonator that is not disposed with the ferroelectric capacitor, wherein the bus waveguide and the part of the outer circumference of the raised ring waveguide have a coupling gap between 400 nm and 500 nm.

11. A method for forming an electro-optic modulator with an integrated memory device, the method comprising:
forming a micro-ring resonator comprising the steps of:
depositing a substrate;
forming an electrode layer on the substrate;
forming a dielectric layer on the electrode layer;
forming a raised ring waveguide on the dielectric layer, wherein the raised ring waveguide comprises a non-centrosymmetric material;
forming the memory device comprising a ferroelectric capacitor formed on a partial circumference of the raised ring waveguide of the micro-ring resonator comprising the steps of:
forming a first transparent electrode on the raised ring waveguide;
forming a ferroelectric layer on the first transparent electrode;
forming a second transparent electrode on the ferroelectric layer such that the ferroelectric layer is interposed between the first and the second transparent electrodes;
generating a first electric field between the first and the second transparent electrodes by applying a first voltage between the first and the second transparent electrodes, the first electric field causing a polarization state of the ferroelectric layer to change based on the strength of the first electric field, wherein the polarization state of the ferroelectric layer remains at the changed state when the first voltage is removed, and
generating an extended electric field between the ferroelectric layer and the electrode layer in response to the first voltage being removed, the extended electric field causing a refractive index of the non-centrosymmetric material to change based on a strength of the extended electric field.

12. The method according to claim 11, further comprising the step of:
generating a second electric field between the electrode layer and the first transparent electrode by applying a second voltage between the first transparent electrode and the electrode layer, the second electric field causing the refractive index of the non-centrosymmetric material to change based on a combined strength of the second electric field and the first electric field.

13. The method according to claim 1, further comprising the step of:
forming a resistive heating element on a non-raised portion of the raised ring waveguide such that the resistive heating element is formed adjacent to an inner circumference of the raised ring waveguide of the micro-ring resonator.

14. The method according to claim 13, further comprising the steps of:
generating heat in the resistive heating element by passing a current through the resistive heating element; and
conducting the heat to the non-centrosymmetric material of the raised ring waveguide to cause the refractive index of the non-centrosymmetric material to change based on a change in temperature of the non-centrosymmetric material.

15. The method according to claim 11, wherein the non-centrosymmetric material comprises Lithium Niobate, Potassium Dihydrogen Phosphate, Gallium Arsenide or Barium Titanate.

16. The method according to claim 11, wherein the ferroelectric layer comprises Hafnium Zirconium Oxide, Barium Titanate, or Lead Zirconate Titanate.

17. The method according to claim 11, wherein the first and second transparent electrodes comprise Indium Tin Oxide.

18. The method according to claim 11, wherein refractive indexes of the first and second transparent electrodes and the ferroelectric layer are lower than a refractive index of the non-centrosymmetric material.

19. The method according to claim 11, wherein a thickness of the first transparent electrode is between 5.5 nm and 6.5 nm.

20. The method according to claim 11 further comprising the step of:
forming a bus waveguide adjacent a part of an outer circumference of the raised ring waveguide of the micro-ring resonator that is not disposed with the ferroelectric capacitor, wherein the bus waveguide and the part of the outer circumference of the raised ring waveguide have a coupling gap between 400 nm and 500 nm.
